(19) United States
(12) Patent Application Publication
(10) Pub. No.: US 2025/0289258 A1
(43) Pub. Date: Sep. 18, 2025

(54) METHOD FOR FORMING MICRO-PATTERN ON SURFACE OF PRODUCT, AND PRODUCT HAVING MICRO-PATTERN FORMED THEREON BY APPLYING METHOD

(71) Applicant: HANKUK UNIVERSITY OF FOREIGN STUDIES RESEARCH & BUSINESS FOUNDATION, Yongin-si (KR)

(72) Inventor: Taekyeong KIM, Yongin-si (KR)

(73) Assignee: HANKUK UNIVERSITY OF FOREIGN STUDIES RESEARCH & BUSINESS FOUNDATION, Yongin-si (KR)

(21) Appl. No.: 19/224,933

(22) Filed: Jun. 2, 2025

Related U.S. Application Data
(63) Continuation of application No. PCT/KR2023/017722, filed on Nov. 7, 2023.

(30) Foreign Application Priority Data
Dec. 8, 2022 (KR) 10-2022-0170883

(51) Int. Cl. B41M 5/24; A44C 27/00; B08B 3/08; B23K 26/364; B41M 3/00; B41M 3/06; B41M 5/00; B44C 1/22; G01Q 10/04; G01Q 60/42; G01Q 80/00; G06K 1/12

(52) U.S. Cl. CPC B41M 5/24; A44C 27/00; B08B 3/08; B23K 26/364; B41M 3/008; B41M 3/06; B41M 5/0011; B41M 5/0058; G01Q 10/045; G01Q 60/42; G01Q 80/00; G06K 1/126; B44C 1/228

(57) ABSTRACT

A method for forming a micro-pattern on a surface of a product and a product including a micro-pattern formed by using the same are disclosed. The disclosed method for forming a micro-pattern on a surface of a product may include checking a roughness and a curvature of a surface of a product on which a micro-pattern is to be formed by scanning, polishing the surface of the product based on a result of checking the roughness and the curvature, forming a micro-pattern comprising at least one groove portion on the surface of the product, inserting a nano insert into the groove portion of the micro-pattern; and forming a protective film on the surface of the product on which the micro pattern is formed.

### TECHNICAL FIELD

The present invention relates to a method of forming a pattern on an object and an article applied thereto, and more particularly to a method for forming a micro-pattern, such as letters, patterns, or pictures on surface of a product and a product including a micro-pattern formed by applying the same.

### BACKGROUND ART

In general, the engraving of letters and symbols on precious metals jewelry and, such as rings, earrings or necklaces, has been done in various forms, depending on the taste and purpose of the designer and consumer.

For example, you can engrave a pattern on a surface such as a ring using a strong tip that melts metal at high temperatures to create and attach a laser to engrave the desired text or image.

However, the patterns engraved on conventional jewelry have a line width and size that is visible to the naked eye, have a limited capacity (number of characters, etc.), and the engraved patterns sometimes damage the unique design of the jewelry. In addition, once engraved, the patterns are difficult to renew or delete. On the other hand, in recent years, the need of pattern formation (engraving) to add various functions and meanings, including theft prevention and counterfeit identification has emerged.

### DISCLOSURE OF THE INVENTION

### Technical Problem

The challenge of technical the present invention is to provide a “method for forming a micro-pattern on surface of a product” that enables a consumer to engrave variety of patterns, such as etc. large quantities of customized text, drawings, photographs (images), and at scale on a nanometer or micrometer desired location on a product, such as, jewelry to erase and renew them at any time in the future.

Furthermore, the technical challenge of the present invention is to provide a “method for forming a micro-pattern on surface of a product” in which enabling the motor stage for and the supporting and moving the product for supporting and moving the tip for the micro-pattern forming are independently so that they do not with each other, thereby from thus excluding the weight of the, product affecting the of more formation of the micro-pattern.

Furthermore, the present technical challenge of invention is to provide a “method for micro-pattern forming on surface of a product” that can be different colors or different by positioning different types of nano-inserts in micro-patterned grooves using dip pen nanolithography technology.

Furthermore, the technical challenge of the present invention is to provide a “method for forming a micro-pattern on surface of a product” that forms micro-patterns that can be easily viewed and read by the consumer/user whenever desired enlarging the with function of a product the zoom-in smart device such as a smartphone.

Furthermore, the present technical challenge of invention is to provide a product comprising a micro-pattern formed by applying the above-mentioned a “method for forming a micro-pattern on surface of a product”.

The problems that the present invention is intended to solve are not limited to those mentioned above, and other problems not mentioned will be understood by those skilled in art from the description following.

### Technical Solution

According to one embodiment of the present invention, there is provided a method of forming a micro-pattern on a surface of the a product, is to be formed to comprising: checking a roughness and a curvature of a surface of a product on which a micro-pattern is to be formed by scanning polishing the surface of the product based on a result of checking the roughness and the curvature, forming a micro-pattern comprising at least one groove portion on the surface of the product, inserting a nano insert into the groove portion of the micro-pattern and forming a protective film on the surface of the product on which the micro pattern is formed.

The step of checking a roughness and a curvature of a surface of a product on which a micro-pattern is to be formed by scanning includes imaging the surface of the product on which the micro pattern is to be formed with an atomic force microscope in a contact, non-contact, or tapping manner in nanometer to micrometer sizes.

The step of polishing the surface of the product includes polishing the surface of the product by rotating an edge of a solid having a higher strength than the product on the surface of the product or using a polishing tip whose an end is flatly polished to a size of several tens of micrometers.

The micro-pattern has a linewidth of from a several nm to a few hundred [symbol] .

The step of forming a micro-pattern includes forming a micropattern using an indentation method of an atomic force microscope.

In a step of forming a micropattern, a micropattern forming device including an XYZ-axis piezo stage on which the tip of the atomic force microscope is mounted and an XYZ-axis motor stage on which the product is mounted is used and the XYZ-axis piezo stage and the XYZ-axis motor stage are configured to be separated from each other and independently movable so as to prevent interference with each other.

A tip of the atomic force microscope is made of diamond material or is coated with diamond.

A spring coefficient (k) of a tip of the atomic force microscope is in a range of 0.1 to 1000 N/m, and a indentation force applied to the product by the tip is in a range of 0.1 nN to 1000 μN.

The step of forming the micro pattern includes forming the micro pattern using a laser machining and ablation method.

A formation of the micropattern using the laser machining and ablation method is performed using a laser in a low vacuum chamber having a vacuum of 10⁻¹ Torr or less, and a wavelength of the laser is in a range of 600 nm to 1200 nm, a power of the laser is in a range of 0.01 W to 100 W, and a pulse width of the laser is in a range of 5 fs (femtoseconds) to 100 ps (picoseconds).

The step of forming the micropatterns is performed using a tip, and when the tip is contaminated with foreign substances, the tip is washed with ethanol and the tip is scanned in a contact manner on a silicon dioxide (SiO2) substrate to restore the quality of the tip.

The nano insert includes one of a nano structure, a nano particle, a bio material, glycerol, a color ink and mixtures thereof.

The nano structure includes a quantum dot, and the quantum dot has a unique color or unique fluorescent characteristic depending on its size.

The comprise method may further comprising: a step of forming an alignment marker in an area adjacent to a portion where the micro pattern is formed on the surface of the product and wherein when second micro pattern is formed on the surface of the product, the alignment marker is used for aligning the second micro pattern to the micro pattern.

The micro pattern cannot be confirmed with the naked eye of a person, but can be confirmed through a zoom-in function of a smart device.

The micro pattern is formed so as to be deleted, changed, updated, and replaced.

The method may further comprise deleting the micropatterns and forming a new micro pattern in a region of the surface of the product where the micro pattern is deleted.

According to another embodiment of the present invention, there is provided a product comprising a micro-pattern formed using the method described above.

The product may include an accessory.

The product may include non-accessory items.

### Advantageous Effects

According to embodiments of the present invention, a “method of forming a micro-pattern on surface of a product” and a product incorporating the can be implemented by engraving on in a customized micro-pattern desired by a consumer a sizes and at a product, such as jewelry and precious metals, an unlimited (or nearly unlimited) microscopic desired location, without compromising the design of the jewelry itself, and by updating and deleting the micro-pattern an unlimited (or nearly unlimited).

Furthermore, embodiments of the present invention provide a “method of forming a micro-pattern on surface of a product” and a product thereof that can be applied to facilitate formation of a micro-pattern product, regardless of the presence or absence of curves irregularities, coatings or contamination, by utilizing a polishing process.

In addition, according to embodiments of the present invention, it is possible to realize a “method of forming a micro-pattern on surface of a product” and a product applying which adopts but the indentation method of an atomic force microscope by independently designing stage a (XYZ motor stage) supporting a product and a XYZ axis piezo supporting tip for indentation so that product does affect the stage supporting the tip, it stable micro-pattern.

Furthermore, embodiments of present invention a “method of forming a micro-pattern on surface of a product” and a product thereof can various and unique properties of positioning various types of nano-inserts into grooves the micro-patterned using dip pen nanolithography technology.

Further, according to embodiments of the present invention, it is possible to implement a “method of forming a micro-pattern on surface of a product” and the product to which it is applied, such that the micro-patterned portion is permanently or semi-permanently preserved by a coating to the protective film formed micro-pattern.

Furthermore, embodiments of the present invention enable a “method of forming a micro-pattern on surface of a product” applying the product that is not but visible to the human eye can be viewed and read with the function of a zoom-in smart device such as a smartphone, thereby allowing to see the consumer/user that the micro-pattern is actually engraved on his/her favorite item (products), stimulating the desire to consumer's purchase/own the item.

Furthermore, according to embodiments of the present invention, it is possible to implement a “method of forming a micro-pattern on surface of a product” and the product applied thereto, wherein various structures (removable elements) are pre-engraved with micro-patterns micro-patterned and are removable to any desired position of the product, thereby enabling the presentation of products more conveniently, efficiently and in various ways.

Furthermore, according to embodiments of the present invention, it is possible to implement a “method of forming a micro-pattern on surface of a product” and the product applied thereto, which can achieve the effect of preventing defects caused by contamination of the tip by presenting various methods for recovering (regenerating) the quality of the tip in the case of forming or repeated micro-patterns on a single on product continuously engraving micro-patterns the same.

However, the effects of the present invention are not limited to the effects above may be extended in various ways without departing from scope of the technical ideas and the present invention.

### BRIEF DESCRIPTION OF THE DRAWINGS

FIG. 1 is a flowchart showing a method of forming a micro-pattern on surface of a product according to one embodiment of the present invention.

FIG. 2 is a flowchart illustrating a method of forming a micro-pattern on surface of a product, in accordance with another embodiment of the present invention.

FIG. 3 is a drawing to illustrate a polishing method that may be applied to form a micro-pattern on a surface of a product, in accordance with one embodiment of the present invention.

FIG. 4 is a diagram illustrating a method of forming a micro-pattern on a surface of a product a method of method of forming (imprinting) a micro-pattern, and an inserting a nano-insert, in accordance with one embodiment of the present invention.

FIG. 5 is a diagram illustrating a method in which of forming a protective film accordance with one embodiment of the present invention, a micro-pattern is formed on surface of a product.

FIG. 6 is a drawing illustrating a product comprising a micropattern formed by applying a method of forming a micropattern on a surface of the product, according to one embodiment of the present invention.

FIG. is 7a perspective view illustrating a micropatterning apparatus that may be used in a method of forming a micropattern on a surface of a product, according to one embodiment of the present invention.

FIG. 8 is a diagram illustrating a method of recovering a tip, which may be applied to a method of forming a micro-pattern on surface of a product, in accordance with one embodiment of the present invention.

FIG. 9 is a schematic view showing the surface of a product before and after removing a previously formed micropattern in a method of forming a micropattern on a surface of a product, according to one embodiment of the present invention.

FIG. 10 is an illustration of an exemplary alignment marker that can be applied to a method of forming a micro-pattern on a surface of a product, in accordance with one embodiment of the present invention.

FIG. 11 is a perspective view to illustrate a method of forming a micro-pattern on surface of a product, in accordance with another embodiment of the present invention.

FIG. 12 is a schematic diagram exemplifying a of, in method forming a micro-pattern on a surface of a product accordance with one embodiment of the present invention and identifying the formed micro-pattern with a device smart.

### BEST MODE FOR CARRYING OUT THE INVENTION

Embodiments of the present invention will now be described in detail with reference to the accompanying drawings, which can be found.

The embodiments of the invention described below are provided to further illustrate the invention to those having ordinary skill art in them, and the scope of the invention is not intended to be limited by the following embodiments, which may be modified in various other ways.

The terms used in this specification are and intended to describe particular embodiments are not intended to limit the invention. Terms used herein in the singular form may include the plural form, unless the context clearly indicates otherwise. Furthermore, the terms “comprise” comprise and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is to mean intended not only that certain elements are directly connected, but also that they are connected by indirectly interposition between them of other elements.

Further, when the present disclosure refers to a member being “located” on another member, this includes not only when a member is abutting another member, but also when there is another between the two members. As used herein, terms the “and/or” includes any one of the enumerated items and any combination of one or more of them. In addition, the terms “about” “substantially” and the like as used in the disclosure are intended are used to mean a range or approximation of that number or degree, taking into account inherent manufacturing and material tolerances, and prevent infringers from taking unfair advantage of disclosures that recite precise or absolute numbers, which are provided for the purpose of illustration.

Embodiments of the present invention will now be described in detail with reference to the accompanying drawings. The thick sizes or parts of the areas or shown in the accompanying drawings may be somewhat exaggerated for clarity and ease of description. Throughout the detailed description, reference numerals like designated like components.

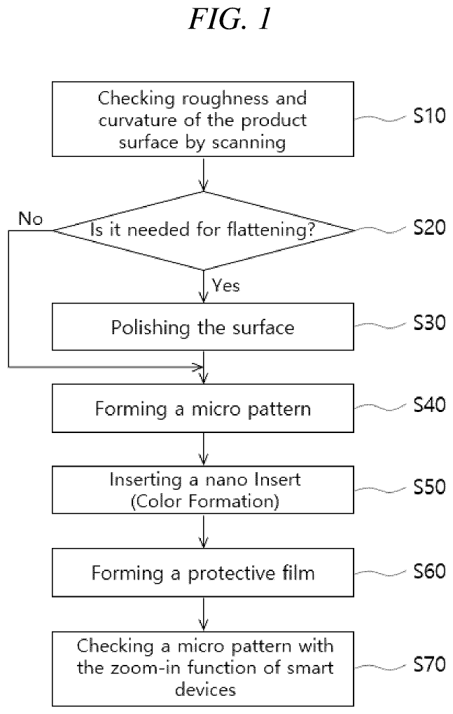

FIG. 1 is a flowchart illustrating a method for forming a micro-pattern on surface of a product, in accordance with one embodiment of the present invention.

Referring to FIG. 1, a method for forming a micro-pattern on surface of a product according to an embodiment of the present invention may include a step (S10) of checking the roughness and curvature of the surface of a product on which a micro pattern is to be formed by scanning, a step (S20) of determining whether flattening of the surface of the product is necessary based on the result of checking the roughness and curvature, a step (S30) of polishing the surface of the product if flattening of the surface of the product is necessary, a step (S40) of forming a micro pattern including at least one of groove portion and at least one of protruding portion on surface of the product, a step (S50) of inserting a nano insert into the groove portion of the micro pattern, and a step (S60) of forming a protective film on a portion of the surface of the product on which the micro pattern is formed.

In the present disclosure, the term ‘micro-pattern’ may refer to a concave structure with repeated grooves and protrusions for engraving characters, patterns, figures, images, etc. Accordingly, the ‘micro-pattern’ may be referred to as a micro-patterned part, or micro-patterned part having grooves and protrusions, or a micro-patterned structure having grooves and protrusions, the like. However, the ‘micro-pattern’ may not have a repeating structure of grooves and protrusions, and the present disclosure may encompass such cases.

In the step (S10) of checking the roughness and curvature by scanning, the surface of the product on which the micro pattern is to be formed is imaged in a contact, non-contact, or tapping manner using an atomic force microscope, i.e., an atomic probe microscope, in nanometer to micrometer sizes, so that the roughness and curvature of the surface of the product can be checked (detected). At this time, by imaging the surface of the product in a size of about 1.5 to 2 times the size of the micro pattern to be formed later, the roughness and curvature of the corresponding surface area can be determined. Here, the roughness and curvature of the surface of the product can be determined in units of nanometers (10 m) or less. In the step (S20) of determining whether flattening is necessary, the polishing step (S30) can be performed only if it is determined that flattening is necessary, and if it is determined that flattening is not necessary, the subsequent micro pattern forming step (S40) can be performed without the polishing process. Therefore, the polishing step (S30) may be an optional process.

In the polishing step (S30) for leveling the curvature of the of surface (initial surface) said product can be performed by, for example, an edge of a solid having a higher strength than said product, on surface of said product at a high speed (e.g., about 1000^{˜}5000 rpm). In this case, the polishing can be performed on an area having a size (width and/or length) of from a the surface of few hundred nm to a few hundred [symbol] of said product. Here, the area to be polished may be from tens of nm² to hundreds [symbol] ², which may vary depending the on shape and number of micro-patterns, etc.

As a method that alternative polishing can be used in the polishing step (S30), the surface of the product can be polished using a polishing tip whose end is flatly ground to a size of several tens of micrometers (width and/or length). For example, if a tip for a noncontact is used in contact mode to scan a silicon dioxide (SiO₂) surface under high humidity, and then the tip end is ground flat, a tip with an end in the micrometers tens can be obtained and be used to polish the surface of the product. In another polishing method, using a polishing tool kit with a sharp tip that is commonly used, it is possible to obtain a flat area on the scale of tens to hundreds of [symbol] , if the polishing tool is approached to the product surface while checking with an optical microscope or digital microscope and the product is polished until the moment the tip contacts the surface of the product.

Furthermore, the operation polishing step (S30), i.e., the polishing, can be performed even if there are pre-formed (imprinted) micro-patterns on the product, i.e., the existing micro-patterns can be deleted and renewed with micro-patterns, new regardless of the number of times.

In the micro-pattern forming step (S40), the micro-pattern may be formed using an indentation method of an atomic force microscope, that is, an atomic probe microscope. Here, the indentation method may be an indentation technique of an atomic force microscope but is not limited thereto and may be extended to any type of technique that forms a micro-pattern (groove, etc.) on a surface with a sharp tip. A nanometer to micrometer-sized micro-pattern in the form of an engraving or embossing can be engraved flattened portion of the product surface, which may be formed by the aforementioned polishing step (S30) or which may exist even without the polishing step (S30), by using by means of means an irradiation indentation method or a tip of an atomic force microscope of laser. Here, a linewidth of the micropattern may be on the of few nm to several hundred [symbol] , and the depth (depth of the portion) of groove of the micropattern may be on the of a few nm to several [symbol] . As an example non-limiting, the linewidth of the micropattern may be in the range of 10 nm to 900 [symbol] and the depth of the micropattern (depth of the groove portion) may be in the range of 1 nm to 900 [symbol] .

In the step (S40) of forming the micro-pattern, a micro-pattern forming device comprising XYZ-axis piezo stage on which is mounted the tip (i.e., probe) of the atomic force microscope and XYZ-axis motor stage on which the product is mounted may be used and XYZ-axis piezo stage and the XYZ-axis motor stage can be configured to be separated from each other and move independently so as to prevent interference with each other. Here, the XYZ-axis piezo stage may be referred to as, a three-axis piezo and the XYZ-axis motor stage be referred to as a three-axis motor stage. in case of forming a micro-pattern by the indentation method of an atomic force of microscope, when placing a heavy product on the piezo stage and scanning it, the piezo stage may be subject to stress. Therefore, embodiments of the present invention can avoid scanning the product on the XYZ-axis piezo stage and allowing the product and tip to move. independently. To accomplish this, the XYZ-axis motor stage can be used to fix the product stably without wobbling.

The tip of the atomic force microscope may be generally made of the highest strength diamond material, or may be a tip coated with diamond. However, the material of the tip may vary depending on the composition of the product to be micro-patterned. Depending on the product material, a tip with the appropriate strength may be used.

The spring coefficient (k) of the tip of the atomic force microscope may be in the range of about 0.1^{˜}1000 N/m, and the indentation force exerted on the product by the tip may be in the range of about 0.1 nN^{˜}1000 μN. When these conditions of spring coefficient and indentation force are satisfied, the formation of a micro-pattern may be more easily accomplished.

According to one embodiment, the micro-patterning step (S40) can be performed using a tip (i.e., a probe), and if tip is contaminated with foreign matter by repeated micro-patterning or like, the tip can be cleaned and with ethanol and can be scanned by contacting a silicon dioxide (SiO₂) substrate to remove the foreign matter and contamination and restore the quality of the tip (regeneration/recovery). The method of regenerating/recovering the tip is exemplary and may vary in some cases. It may be important to ensure that the tip and the cantilever on which it is mounted are damaged not during the process of regenerating/recovering. The recovered/regenerated tip can then use to be perform the micro-patterning operation again.

In another embodiment, micro-pattern may be formed using a laser machining and ablation method in micro-pattern forming step (S40). In this case, the formation of the micro-pattern using the laser machining and ablation method may be performed using a laser in a low vacuum chamber having a vacuum of about 10⁻¹ Torr or less. As lasers, for example, a Ti:sapphire laser or an Nd:YAG laser may be used. The wavelength of the laser may be in the range of about 600 nm^{˜}1200 nm, the power of the laser may be in the range of about 0.01 W^{˜}100 W, and the pulse duration of the laser may be in the of about 5 fs (femtoseconds) 100 ps^{˜}(picoseconds). When the above conditions are satisfied, micro patterns can be easily formed using a laser having high energy. Depending on the type or strength of the product to be micro-patterned, the values size of the micro-pattern, and like the above may be adjusted and used.

In the step (S50) of inserting the nano-inserts, various types of nano-inserts can be positioned in the embossed or imprinted patterned grooves (indentations on surface of the product dip pen nanolithography technology. The insertion step (S50) of the nano-inserts may include or color forming step to color the nano-patterns, the step color forming may be performed separately after the step (S50) of inserting the nano-inserts. The nano inserts may have a diameter, for example, from about 1 nm to 500 nm. The nano inserts may comprise any one of nanostructures, nanoparticles, biomaterials, glycerol, color inks, and mixtures thereof. For example, the nanostructures may include quantum dots, where in quantum they have a unique color or unique fluorescent properties depending on their size. Different sizes of quantum dots can have unique color or fluorescence properties depending on their size, which can be incorporated into the micro-patterned nanostructures portion of them to accommodate consumer-desired colors. Nanoparticles of metals gold, silver, copper, and other, thereof and mixtures, can also be placed in the micro-patterned areas. In addition, biological materials such as DNA, cells, nucleic acids, or proteins are possible, and various other nanoparticles, glycerol, and colored inks can be inserted into the micro-patterned areas according to consumer's preference

In the step of forming a protective film (S60), a protective film may be formed on the micropatterned portion of the product. In order to prevent foreign matter from getting stuck in the micropatterned part of the product (i.e., the imprinted part), rusting, etc., only the part can be coated or colored with a protective film to improve durability. Furthermore, after such an operation, a process (curing process) such as temperature control (heating) or light irradiation may be performed to stably harden the protective film (layer/colored layer) coating. The conditions of the above curing process may vary depending on the material of the product and the material of the protective film. The formation of the protective film may be carried out using a shadow mask to protect while the entire product allowing the coating to proceed only on the parts finely patterned, and after the shadow mask is formed, the coating applied application using a to spray method or a soft brush method, etc. minimize the impact on the itself product. The material to be coated by method spray may be selected differently depending on the type of jewelry and precious metal and may be commercially available.

The micro-patterns formed in an embodiment of the present invention may not be visible to eye the human but can be enlarged and confirmed through a zoom-in function of a device smart such as a smartphone. In this regard, the method of forming a micro-pattern on surface of a product according to an embodiment of the present invention may further comprise a step (S70) of confirming the micro-pattern formed on the product with function of a zoom-in smart device. Here, the smart device may include a smartphone and a tablet PC (personal computer). According to embodiments of the present invention, by enabling the micro-patterns to be viewed read with the zoom-in function of a smart device such as a smartphone, the consumer/user can see that the micro-patterns are actually engraved on his/her favorite product thereby stimulating the consumer's desire to purchase/own. For example, the finished micro-patterned product can be viewed using a smartphone's zoom-in function (e.g., zooming in to of about 50× or mores) the consumer/user can easily view/read at any time during their daily routine. This can greatly increase consumer/user satisfaction, as it can prove to the consumer that the micro-pattern is indeed engraved on their favorite product, even though the pattern is not discernible to the naked eye.

According to an embodiment of the present invention, said micro-pattern may be formed such that can be it replaced deleted, altered, renewed and. Thus, the method of forming a micro-pattern on surface of the product may further comprise the step of deleting the micro-pattern and forming a new micro-pattern in the region where the micro-pattern has been deleted on surface of the product. The micro-pattern and the region where is formed the protective film may erasable be and renewable with a pattern at new anytime desired by the consumer/user. This process may be accomplished by re-polishing the existing micro-patterned portion. Since polishing with depth of tens of nm to hundreds of nm (i.e., 10⁻⁸ m to 10⁻⁷) m) differs by a factor of 100,000 or more compared to the rim thickness size of a typical piece of jewelry (e.g. a ring) of a few mm (10⁻³ m), it does not be possible to map visually identify the polishing effect. Therefore, the original jewelry will not show any significant changes and can be renewed several times over.

The method of forming a micropattern on surface of a product according to an embodiment of the present invention may further comprise the step of forming an alignment marker in a region adjacent to the portion of the surface of the product on which the micropattern is formed, and upon formation of a second micropattern on surface of product, the alignment marker may be utilized for aligning the second micropattern with respect to the micropattern. The step of forming said alignment marker may be performed, for example, after step (S50), but in cases some may be performed during steps (S40) and (S50).

When the formation of micro-patterns is required in multiple areas of the product, the of the micro-patterns can be performed by moving the product at regular intervals using a motorized XYZ-axis moto stage. In addition, if a series of micro-patterns are to be imprinted on the same product at different times (e.g, for each anniversary), alignment markers can be marked on the corners four of the area, first imprinted which then be used for alignment with the next micro-pattern. In addition, in order to ensure that the newly formed micro-patterns are consistently imprinted under the same conditions (or nearly the same conditions) as the size of the indentation depth and previously formed micro-patterns, the imprinting conditions (e.g., contact force, scan rate, external temperature, humidity, etc.) can recorded and stored. In this case, if the spacing between the corners and the area center value of previously micro-patterned are stored in the program, it is possible to form a micro-pattern of size a certain during further micro-patterning operations.

Furthermore, in order to prevent the micro-patterned area from in the future, being lost the shape of the area around the micro-patterned area can be identified and stored in advance, such as at so by measuring/taking an atomic force microscope topography image, an optical image, and a smartphone zoom image about 2^{˜}100× around, that the consumer/user can easily locate the micro-pattern in future. This can help in selecting the spot where additional micro-patterns are to be imprinted by making it easier to locate the initial imprinting spot when additional imprints are required in the future.

According to embodiments, micro-patterns can be imprinted on the product (jewelry, ornaments, etc.), but the design can also such that be the micro-patterns can be imprinted in advance on small samples (shape, form, material type, color, etc. be can selected according to the consumer/user's preference) and then at least one of them can applied to be the product in a removable manner.

The method used in the step (S40) of forming the nanopattern according to one embodiment of the present invention may refer to be scanning probe lithography. By using the above scanning probe lithography, compared to other nanolithography techniques, it is possible to form micro-patterns directly on the finished product without etching, exposure, contacting with a solution, etc., i.e., after the product is finished, the micro-patterns can be formed on the be product. Therefore, this method of forming micro-patterns can be said to have excellent preservation properties for goods.

The micropatterning methods described above are not limited to creating grooves on surface of the product by indentation and inserting various nano inserts therein. In method another micro-patterning, it also possible to is form a micro-patterns on applying is the precious metals surface of the of jewelry and by voltage in the range of about 0.1V^{˜}100V (the voltage magnitude adjusted according to the type) and structure of the product between the tip and the product, so that oxidation occurs on surface the product. Humidity conditions of about 60% or more may be required for the formation of these micro-oxidized patterns, and the formation of a protective film may preserve the micro-oxidized patterns permanently or semi-permanently. Furthermore, as mentioned above, other methods of forming micro-patterns include micro-patterns using laser processing and ablation methods.

Furthermore, the above-described indentation method for forming micro-patterns is not limited to scanning probe lithography. For example, other nanolithography techniques also can be applied to form micro-patterns on products such as jewelry and precious metals. Furthermore, the above-described indentation for forming micro-patterns is not to simply utilize a single cantilever-tip combination but can also include comprising a cantilever-tip array a of cantilever-tips to form micro-patterns a large.

The products (articles) subject to imprinting of the above-described micropatterns (phrases, poems, drawings, realistic photographs, etc.) may include accessory or non-accessory items. The products (items) are not limited to jewelry and precious metals such as rings, earrings, necklaces, bracelets, etc., but also include various antiques and collectibles owned by consumers/users, refrigerator magnets, souvenirs, pens, glasses, vases, children's toys, children's name tags ( )useful if you don't want to reveal your address, musical instruments, teeth (including artificial teeth), photos, credit cards, student IDs, spoons, children's cutlery first, watches, handbags, phone cases, picture frames, trophies, medals, glass bottles, beverage containers liquor bottles water bottles, etc. By directly nano-writing/pictures instead of labels on the above products ( )articles, it can used for a variety of purposes, such as anti-theft markings, identifying counterfeits, numbers, engraving serial engraving the original author's or photo on the product, displaying traditional patterns for to gifts foreigners, various commercial characters/symbols through, or emphasizing (the rarity of product limited edition and handwritten, etc.). The above categories of products (articles) can be extended to any solid material on which the consumer/user wishes to form a micro-pattern.

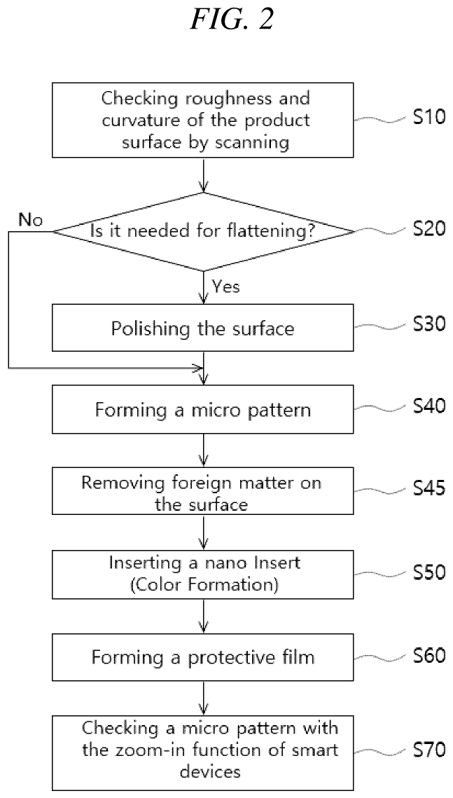

FIG. 2 is a flowchart illustrating a method of forming a micro-pattern on surface of a product, in accordance with another embodiment of the present invention.

Referring to FIG. 2, the method of forming a micro-pattern on surface of a product according to the present embodiment may further include a step (S45) of removing foreign matter on surface of the product between the micro-pattern forming step (S40) and the insertion step (S50) of the nano-insert described in FIG. 1. Some foreign or substances residues may occur around the groove portion formed in the micro-pattern forming step (S40), and these may be removed by the foreign substance removal step (S45). For example, a soft brush or like with used an alcohol-based solvent or a such as ethanol ketone-based solvent such as acetone may be to brush the surface of the product lightly remove the foreign matter or residue. In this case, the formation of a sharper and cleaner micro-pattern may be possible. In FIG. 2, the remaining method may be the as described in FIG. 1 except that a foreign object removal step (S45) is added.

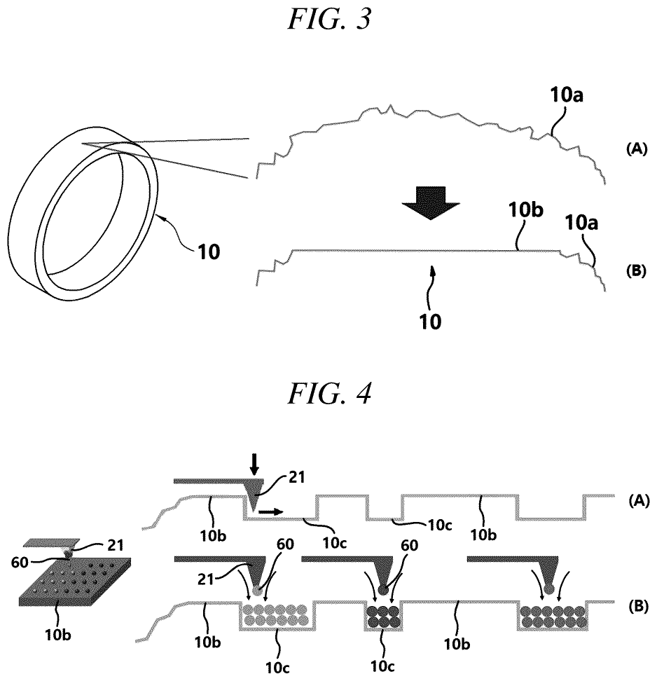

FIG. 3 is a drawing to illustrate a polishing method that may be applied to form a micro-pattern on a surface of a product, in accordance with one embodiment of the present invention.

Referring to FIG. 3, the roughness and curvature surface (10a) of the product (10) on which the micro-pattern is to be formed can be checked by scanning, and if, as, a result of checking said roughness and curvature the surface (10a) of the of the product (10) needs to be smoothed, the product can be polished to form a smoothed portion 10b. Here, the product (10) may exemplarily be a ring. The surface (10a) of the product (10) can be scanned to determine if the roughness and curvature is severe so, as shown in (A) and (B) a polishing operation performed can be to form the flattened portion (10b) to imprint a pattern, fine as shown in.

The surface (10a) of the product (10) can be scanned to be first obtain a topography image. At this time, at the location where at the micro-pattern is to be formed, the by imaging bends, roughness, structure, etc. of the area can be checked a size of that is (about 1.5^{˜}times larger than the micro-pattern full size). For example, the imaging operation can be performed in a contact mode, a noncontact mode, or a tapping using the tip to minimize damage to the surface of the product (10). The tip may be, as an example non-limiting, a silicon tip, but its material may vary. A method polishing process can then be performed on surface (10a), according to the previously described.

FIG. 4 is a diagram illustrating a method of forming a micro-pattern on surface of a product a method of method of forming (imprinting) a micro-pattern, and an inserting a nano-insert, in accordance with one embodiment of the present invention.

Referring to FIG. 4, (A) a micro-pattern (10c) comprising a groove portion can formed be on the flattened surface (10b) of the product as shown in. In this case, the micro-pattern (10c) can be formed by indentation using the tip (21) [i.e., the] of microscope probe atomic force. The (10c) can be by indenting and dragging the tip (21).

Additionally, (B) nano inserts (60) can be inserted into the grooved portions of the micropattern (10c) as shown in. For example, various types of nano-inserts (60) can be positioned in the grooved portion of micro-pattern (10c) using dip pen nanolithography techniques. For example, the nano inserts (60) can include quantum dots. Different sized quantum dots can have unique color or fluorescence properties depending on their size, which can be applied to the micro-patterned portion in consideration of the color desired consumer/user. As described above, metals gold, silver, copper, and various, and mixtures thereof, can also be portioned. In addition, biological materials such as DNA, cells, nucleic acids, or proteins are possible also, and various other nanoparticles, glycerol, and colored inks can be placed on the micro-patterned areas to the preferences of suit the user consumer/company.

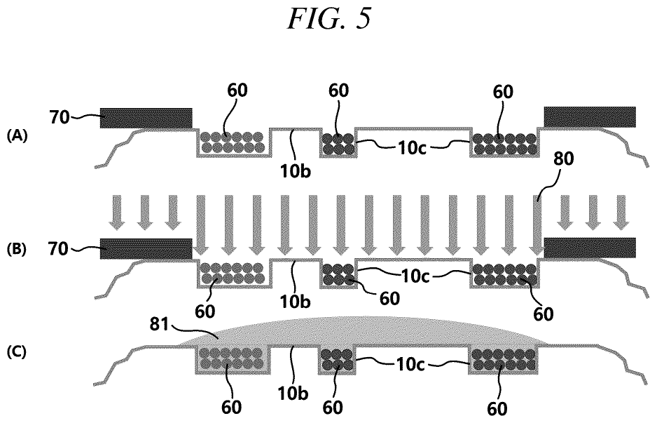

FIG. 5 is a diagram illustrating a method in a method of forming a protective film forming a micro-pattern on a surface of a product, according to one embodiment of the present invention.

Referring to FIG. 5, as shown in (A), where the micro-pattern (10c) is formed on surface (10b) of the product (10) and color expression is finished by the insertion of the nano-insert (60), a mask (70) can be formed in the remaining portion of the except for the portion. In other words, The surrounding area of the portion where the micro-pattern (10c) is formed can be masked with the shadow mask (70).

The coating material (80) can be applied (supplied) by spraying or soft brushing, as shown in Figures (B) and (C), and after a period time, the shadow mask (70) can be removed. Reference numeral (81) shows a formed protective film. Protective film 81 may be formed to cover the area in and around the portion where the micro-pattern (10c) is formed. In other words, the protective film (81) may be formed to cover the grooved portions and of the micro-pattern (10c), the protruding portions therebetween, and the area surrounding them.

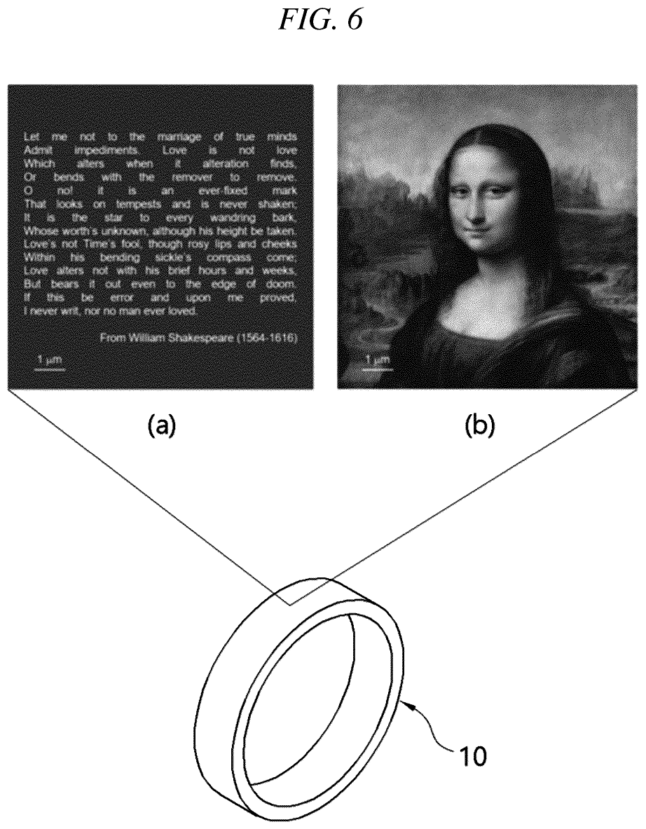

FIG. 6 is a drawing illustrating a product comprising a micropattern formed by applying a method of forming a micropattern on surface of the product, in accordance with one embodiment of the present invention.

Referring to FIG. 6, in embodiments of the present invention, the micropatterned product may be imprinted with micropatterned characters, or images that are not visible to the naked eye, but can only under as be seen described above. Such characters, patterns, or images may be in both color and black and white. Here, (a) shows case where the micropattern is with characters engraved, and (b) shows a case where the micropattern is with images engraved such as drawings or photographs. These markings are the same as in FIGS. 10 through 12.

As such, since the micro-patterns are difficult to see with the naked eye, personal information or other privacy-related information may not be exposed, and the owners of the product can be reassured about security issues such as the exposure of personal information.

FIG. is 7a perspective view illustrating a micropatterning apparatus that may be used in a method of forming a micropattern on a surface of a product, according to one embodiment of the present invention.

Referring to FIG. 7, an apparatus that may be used in a method of forming a micropattern on a surface of a product according to embodiments of the present invention may stages (20, 30). The XYZ-axis piezo stage 20 and the XYZ-axis motor stage (30) may be of each other, so that they may not each other's vibrations, etc. The XYZ-axis stage (20) may be installed on the frame (25) such that the first stage (24) be driven motion in a fine linear in the direction of the two axes (X, Y) axes, and first the second stage second (23) may be (23) installed on such that the stage (24) the may be moved motion in a in the fine linear vertical direction (axis Furthermore, the tip (21) on second stage (23) may have the cantilever (22), ie., a columnar part (support). Meanwhile, axis the XYZ motor stage (30) may configured to be motor-driven, and the first stage (32) can be installed on the frame (31) so that it can be linearly driven along one axis (X-axis) and the second stage (33) can be installed on the first stage (32) so that it can be linearly driven along another axis (Y-axis). A third stage (34) can be installed on the upper part of the second stage (33) so that it can be raised and lowered in the Z-axis direction, which is the height direction, and the product (10) can be fixed to the upper surface of the third stage (34) by a chuck (34a).

According to one embodiment, once the location has been determined to be imprinted with the micropattern, the tip (21) can be positioned to be centered at the location where the micropattern is to be formed. The required wording, drawing, photograph, etc. can be received and stored in the input of the scanning lithography controller, and then recalled just before the micro-patterning and to the movement of linked the tip. At this time, the desired indentation depth the indentation can be set by adjusting force. Once has begun, the scanning lithography process vibration and noise should be avoided as much as possible to ensure stable operation. If necessary, axis the XYZ motor stage (30) can be mounted an optical table or optical breadboard to eliminate or vibration and other generation.

Depending on the ambient conditions, the indentation conditions may vary due to the water meniscus between the tip (21) and the surface of the product (10). In other words, at the atoms the nanometer scale, at (21) the tip can be subjected to a large pressure (pressure=F/A where A=contact area, F=force) with force, a small which can cause wear on the tip (21) during micropatterning and scanning. To avoid this, one solution may be to perform the micropatterning and scanning under low humidity conditions (using a glove box) of about 20^{˜}30% or less. These anti-wear conditions may vary depending on the type of metal (i.e., the material of the product) and the surface condition. However, in some cases, high humidity conditions of about 60% or more may be desirable when performing micropatterning on surface of a high-strength product (10). On the other hand, when imprinting by a fine patterning on fragile surface such as glass, it is prevent possible to damage to the product by adjusting the pressing force value and speed.

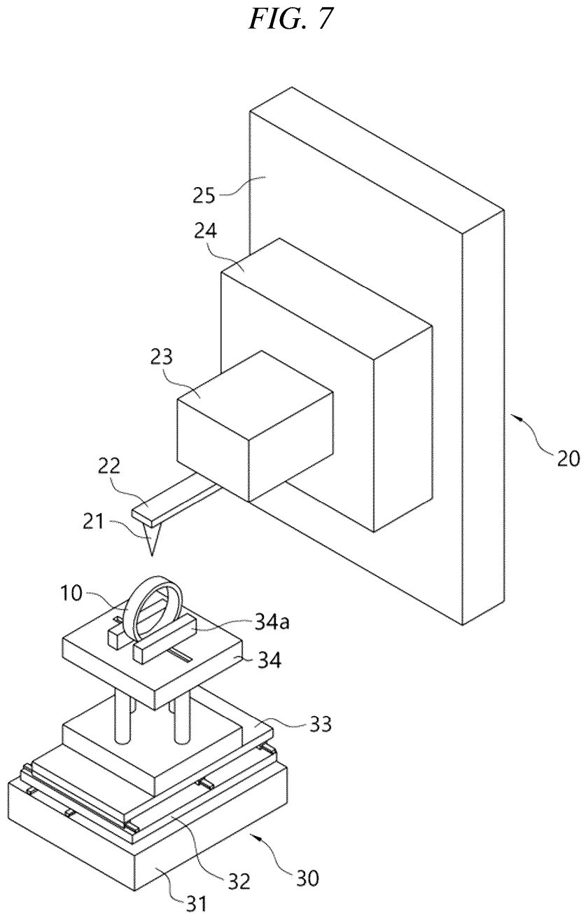

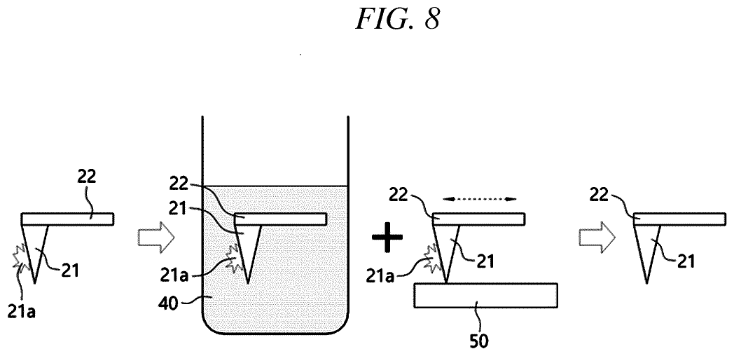

FIG. 8 is a diagram illustrating a method of regenerating/recovering a tip that can be applied to form a micro-pattern on surface of a product, in accordance with one embodiment of the present invention.

Referring to now of the present FIG. 8, there is illustrated an exemplary method of rejuvenating (regenerating/recovering) a tip that may be used in a method of forming micro-patterns on surface of a product according to embodiments invention. If the if tip (21) mounted on the cantilever (22) is contaminated is contaminated with by foreign matter (21a) or the tip (21) multiple operations, the foreign matter (21a) and contamination can be can removed and (21) the quality of the tip be regenerated by soaking or the tip in ethanol (40) by rubbing the tip (21) against a silicon dioxide (SiO₂) substrate (50) multiple times. However, the method of regenerating the tip (21) described herein is exemplary and may be varied in some cases.

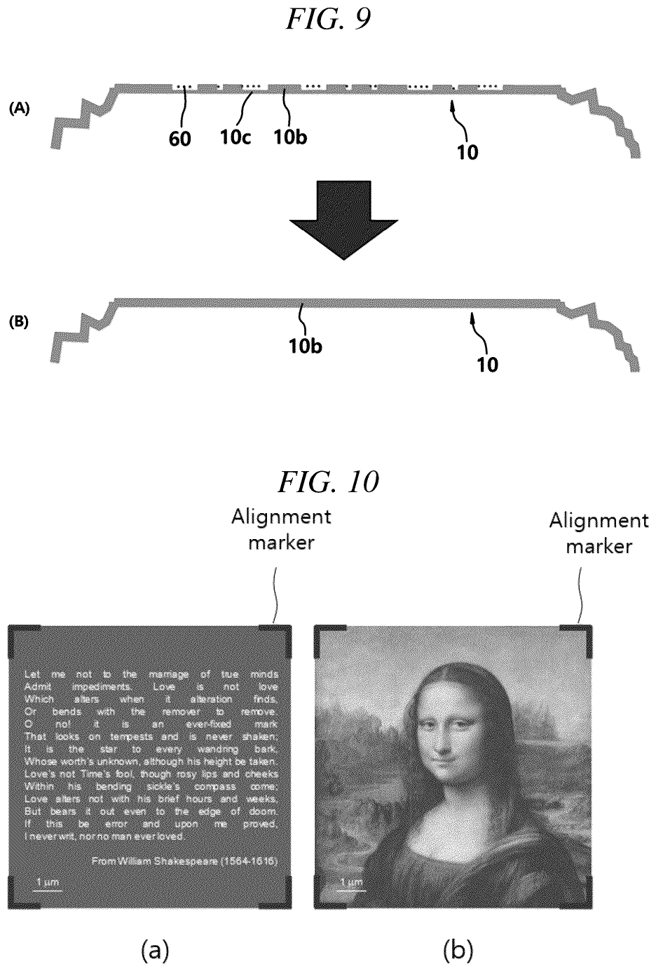

FIG. 9 is a schematic view showing the surface of a product before and after removing a previously formed micropattern in a method of forming a micropattern on a surface of a product, according to one embodiment of the present invention.

Referring to now of the present FIG. 9, exemplary product surfaces are shown before and after removing a previously formed micropattern in a method of forming a micropattern on surface of a product according to an embodiment invention. (A) the drawing is a state before removing the micro-pattern, and (B) the drawing is a state after removing the micro-pattern. (A), In Figure the micro-patterns may be exaggerated. In the case of a product (10) having an existing micro-pattern (10c), it is removing by a polishing operation, as described above, can be flattened portion (10b) on which can be a micro-pattern new.

FIG. 10 is an illustration of an exemplary alignment marker that can be applied to a method of forming a micro-pattern on a surface of a product, in accordance with one embodiment of the present invention.

Referring to FIG. 10, an alignment marker may be separately imprinted on the area where the micropattern is formed. For example, the markers alignment may be formed at the micro-patterned. The marker alignment may be used for positioning position, spacing, and parallelizing otherwise adjusting the of the micro-patterns with respect each other to when additional micro-patterns are formed or repeatedly formed in the future.

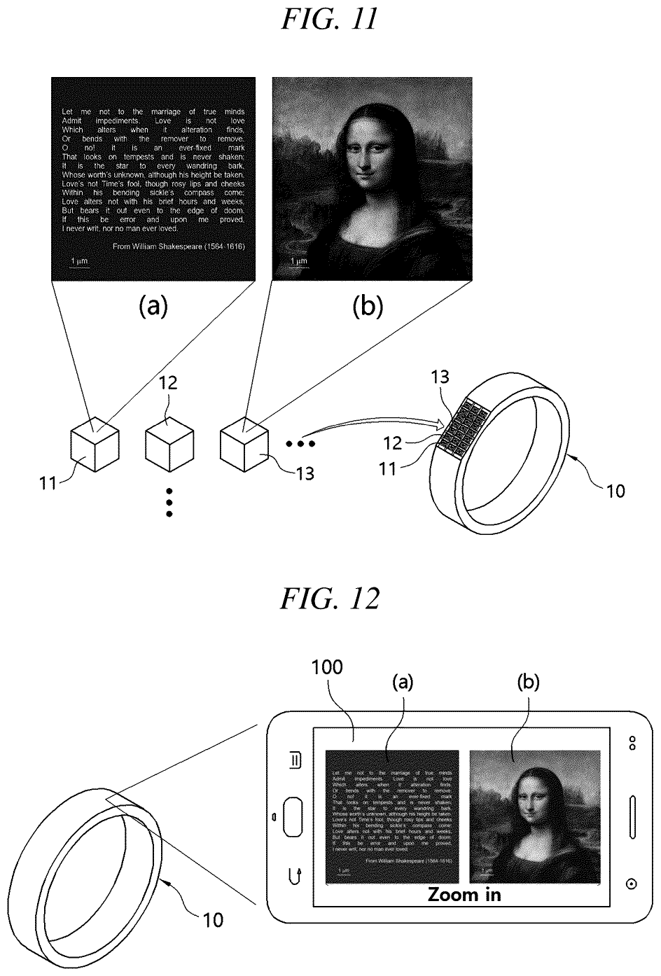

FIG. 11 is a perspective view to illustrate a method of forming a micro-pattern on surface of a product, in accordance with another embodiment of the present invention.

Referring to now of the present FIG. 11, there shown a is method of method forming micro-patterns on surface of a product according to another embodiment invention, and a product having applied. Here the, micro-patterns may not be formed directly on the main body of product (10), but rather the micro-patterns desired may be formed on other substrates or structures (11, 12, 13), i.e., “removable elements”, and then a selection of these structures (11, 12, 13) may be attached to the product (10) for use. For example, a yearly anniversary can be commemorated by imprinting an image of a micro-pattern on a new substrate (structure) and attaching the product (10). Here, the structures (11, 12, 13) may be, for example, ornaments or jewelry, but are not limited thereto. By making them pre-engraving micro-patterns on the various structures (removable elements) and removable to any desired location on the product, it may be possible to create micro-patterned products more conveniently, efficiently and in a variety of ways.

FIG. 12 is a schematic diagram exemplifying a method forming a micro-pattern on surface of a product accordance with one embodiment of the present invention and identifying the formed micro-pattern with a smart device.

Referring to now of the present FIG. 12, there shown a is perspective view of, and a product having a micro-pattern formed on its surface in accordance with an embodiment invention an image of the micro-pattern being viewed with a smartphone (100). In the case of a micro-pattern formed on a ring, actual product (10), which may not be possible to see with the naked eye. However, as described above, the image of the micro-pattern of the micro-pattern can be confirmed by enlarging image using a smart device (electronic device) capable of enlarging image. Here, an exemplary case which illustrated in, but the micro-pattern of the product (10) is checked on the screen of the smartphone (100) by enlarging the image by times (100) using the zoom-in function of the smartphone (100) the enlargement magnification can be varied. Although it is unable, the naked eye to see the image or text of the fine pattern engraved on the product (10) the zoom function can be utilized to make it read it easier for consumer/user see and at any time of the day night or. Although the fine pattern is not identifiable with the naked eye the consumer/user can confirm that the fine pattern is actually engraved on his/her favorite item, etc., so this confirmation function can stimulate the desire to consume.

According to the embodiments of the present invention described above, it is possible to implement the “ ” same, method of forming a micro-pattern on a surface of a product and a product comprising the by engraving a micro-pattern customized desired by a consumer on location, a in of micro-sizes and at a product, such as jewelry and precious metals, an unlimited (or nearly unlimited) desired without detracting from the itself design of the jewelry and by updating and deleting the micro-pattern an unlimited (or nearly unlimited. Furthermore, embodiments of the present invention can implement a “method of forming a micro-pattern on surface of product” and a product applying the micro-pattern on surface of a on surface of the a the by utilizing product, wherein can be micro-pattern easily formed a polishing process, regardless of the bends irregularities, coatings, or contamination. Furthermore, according to embodiments of the present invention, a “method of forming a forming a micro-pattern on surface of product” and the product applied thereto can be realized by adopting but by the indentation method of an atomic force microscope, independently designing a stage supporting product (XYZ motor stage) and a (supporting the tip for indentation XYZ axis) product affect stage supporting the tip, and thus, the micro-pattern stably.

Further, according to embodiments of the present invention, it is possible to same a “method of forming a forming a micro-pattern on surface of product” and a product applying the, wherein be various kinds of nano-inserts can positioned in the grooves micro-patterned using dip pen nanolithography technology to and unique properties of the Furthermore, according to embodiments of the present invention, it is possible to implement a “method of forming a forming a micro-pattern on surface of product” and a product applying, wherein by the micro-patterned portion can be permanently or semi-permanently preserved a coating to protective film the formed micro-pattern. Furthermore, according to embodiments of the present invention, it is possible to implement a “method for forming a micro-pattern on a surface of product” and a product applying the wherein the micro-pattern is not but visible to eye the human can be viewed and read by a zoom-in function of a smart device such as a smart smartphone, thereby allowing to see the consumer/user that the is micro-pattern actually engraved on his/her favorite item (product), thereby stimulating the desire to consumer's purchase/own the item.

Furthermore, embodiments of present invention provide a “method of forming a forming a micro-pattern on surface of product” and a product with the same, wherein the micro-pattern can be engraved in advance on various structures (detachable elements) and can be detachable at a desired location on the product, making it more convenient, efficient, and versatile to produce a micro-patterned product. Furthermore, according to embodiments of the present invention, a “method of forming a forming a micro-pattern on surface of product” and the product applied thereto can be implemented to prevent defects caused by contamination of the tip by providing various methods for recovering regenerating the quality of the in the case of forming or repeated micro-patterns on a single on product continuously engraving micro-patterns the same.

This description discloses, and preferred embodiments of the present invention although certain terms are used, they are used in sense a general only to facilitate the description and understanding of the invention are not intended limit the scope of the invention. In addition to the embodiments disclosed herein other modifications based on technical ideas of the present invention will be apparent to those of ordinary skill in the art to which the present invention belongs. One having ordinary knowledge in the art a product will recognize that the method of forming micro-patterns the micro-patterns on surface of according to the embodiments described with reference to FIGS. 1 to 12, and the product comprising formed thereby, be variously may substituted, altered, and modified without departing from the technical idea of the invention. The scope of the invention is therefore not to be defined by the embodiments described, but by the technical i recited in the claims.

### INDUSTRIAL AVAILABILITY

Embodiments of the present invention can be applied in the art of forming patterns on objects and articles related thereto.

1. A method for forming a micro pattern on a surface of a product, comprising:
checking a roughness and a curvature of a surface of a product on which a micro-pattern is to be formed by scanning;
polishing the surface of the product based on a result of checking the roughness and the curvature;
forming a micro-pattern comprising at least one of groove portion on the surface of the product;
inserting a nano insert into the groove portion of the micro-pattern; and
forming a protective film on the surface of the product on which the micro pattern is formed.

2. The method for forming a micro pattern on a surface of a product according to claim 1, wherein the step of checking a roughness and a curvature of a surface of a product on which a micro-pattern is to be formed by scanning includes imaging the surface of the product on which the micro pattern is to be formed with an atomic force microscope in a contact, non-contact, or tapping manner in nanometer to micrometer sizes.

3. The method for forming a micro pattern on a surface of a product according to claim 1, wherein the step of polishing the surface of the product includes polishing the surface of the product by rotating an edge of a solid having a higher strength than the product on the surface of the product or using a polishing tip whose an end is flatly polished to a size of several tens of micrometers.

4. The method for forming a micro pattern on a surface of a product according to claim 1, wherein the micro-pattern has a linewidth of from a several nm to a few hundred μm.

5. The method for forming a micro pattern on a surface of a product according to claim 1, wherein a step of forming a micro-pattern includes forming a micropattern using an indentation method of an atomic force microscope.

6. The method for forming a micro pattern on a surface of a product according to claim 5, wherein in a step of forming a micropattern, a micropattern forming device including an XYZ-axis piezo stage on which the tip of the atomic force microscope is mounted and an XYZ-axis motor stage on which the product is mounted is used, and
the XYZ-axis piezo stage and the XYZ-axis motor stage are configured to be separated from each other and independently movable so as to prevent interference with each other.

7. The method for forming a micro pattern on a surface of a product according to claim 5, wherein a tip of the atomic force microscope is made of diamond material or is coated with diamond.

8. The method for forming a micro pattern on a surface of a product according to claim 5, wherein a spring coefficient (k) of a tip of the atomic force microscope is in a range of 0.1 to 1000 N/m, and a indentation force applied to the product by the tip is in a range of 0.1 nN to 1000 μN.

9. The method for forming a micro pattern on a surface of a product according to claim 1, wherein the step of forming the micro pattern includes forming the micro pattern using a laser machining and ablation method.

10. The method for forming a micro pattern on a surface of a product according to claim 9, wherein a formation of the micropattern using the laser machining and ablation method is performed using a laser in a low vacuum chamber having a vacuum of 10⁻¹ Torr or less, and
a wavelength of the laser is in a range of 600 nm to 1200 nm, a power of the laser is in a range of 0.01 W to 100 W, and a pulse width of the laser is in a range of 5 fs (femtoseconds) to 100 ps (picoseconds).

11. The method for forming a micro pattern on a surface of a product according to claim 1, wherein the step of forming the micropatterns is performed using a tip, as the tip is contaminated with foreign substances, the tip is washed with ethanol and the tip is scanned in a contact manner on a silicon dioxide (SiO2) substrate to restore the quality of the tip.

12. The method for forming a micro pattern on a surface of a product according to claim 1, wherein the nano insert includes one of a nano structure, a nano particle, a bio material, glycerol, a color ink, and a mixture thereof.

13. The method for forming a micro pattern on a surface of a product according to claim 12, wherein the nano structure includes a quantum dot, and the quantum dot has a unique color or unique fluorescent characteristic depending on a size.

14. The method for forming a micro pattern on a surface of a product according to claim 1, further comprising: a step of forming an alignment marker in an area adjacent to a portion where the micro pattern is formed on the surface of the product, wherein as second micro pattern is formed on the surface of the product, the alignment marker is used for aligning the second micro pattern to the micro pattern.

15. The method for forming a micro pattern on a surface of a product according to claim 1, wherein the micro pattern cannot be confirmed with the naked eye of a person, but can be confirmed through a zoom-in function of a smart device.

16. The method for forming a micro pattern on a surface of a product according to claim 1, wherein the micro pattern is formed so as to be deleted, changed, updated, and replaced.

17. The method for forming a micro pattern on a surface of a product according to claim 1, further comprising:
deleting the micropatterns; and
forming a new micro pattern in a region of the surface of the product where the micro pattern is deleted.

18. A product comprising a micro pattern formed using the method of any one of claim 1.

19. The product comprising a micro pattern formed according to claim 18, wherein the product includes an accessory.

20. The product comprising a micro pattern formed according to claim 18, wherein the product includes a non-accessory item.
